(19) United States
(12) Patent Application Publication
(10) Pub. No.: US 2025/0265182 A1
(43) Pub. Date: Aug. 21, 2025

(54) METHODS, APPARATUS, AND ARTICLES OF MANUFACTURE TO THROTTLE MEMORY BANDWIDTH FOR POWER MANAGEMENT

(71) Applicant: Intel Corporation, Santa Clara, CA (US)

(72) Inventors: Shekoufeh Qawami, El Dorado Hills, CA (US); Vijay Anand Mathiyalagan, Austin, TX (US); Anna Querbach, Bellingham, WA (US); Casey Winkel, Hillsboro, OR (US)

(73) Assignee: Intel Corporation, Santa Clara, CA (US)

(21) Appl. No.: 19/197,712

(22) Filed: May 2, 2025

(51) Int. Cl. G06F 12/02

(52) U.S. Cl. CPC G06F 12/0223

(57) ABSTRACT

Systems, apparatus, articles of manufacture, and methods are disclosed to throttle memory bandwidth for power management. An example apparatus includes machine-readable instructions and at least one programmable circuit to be programmed by the machine-readable instructions. The at least one programmable circuit is to determine an output power from a power management circuit of a memory, determine an input power to the power management circuit based on the output power, and based on the input power and a threshold power, adjust a bandwidth control setting of the memory.

### BACKGROUND

Compute platforms (e.g., a laptop computer, a server, etc.) include one or more programmable circuits, memory and/or storage, and/or one or more peripheral devices. In a compute platform, a programmable circuit, such as a central processor unit (CPU), a graphics processor unit (GPU), a Field Programmable Gate Array (FPGA), etc., is in communication with one or more devices. For example, a programmable circuit is coupled to one or more peripheral devices (e.g., a display, a keyboard, a printer, etc.), a network (e.g., wired or wireless), memory, and/or storage. In computing applications, devices can communicate via one or more communication interfaces. Devices can communicate via a wired interface, an optical interface, and/or a wireless interface. In a wired network, devices may communicate via a communication bus.

### BRIEF DESCRIPTION OF THE DRAWINGS

FIG. 1 is a block diagram of an example compute platform in which an example compute device includes example power management unit (PMU) circuitry to throttle bandwidth between the compute device and example memory on a per-memory instance basis.

FIG. 2 is a block diagram of an example implementation of the PMU circuitry of FIG. 1.

FIG. 3 is a flowchart representative of example machine-readable instructions and/or example operations that may be executed, instantiated, and/or performed by example programmable circuitry to implement the PMU circuitry of FIG. 2.

FIG. 4 is a flowchart representative of example machine-readable instructions and/or example operations that may be executed, instantiated, and/or performed by example programmable circuitry to implement the control circuitry of FIG. 2.

FIG. 5 is a graphical illustration depicting power throttling based on an example threshold input power of 12.5 watts (W).

FIG. 6 is a block diagram of an example processing platform including programmable circuitry structured to execute, instantiate, and/or perform the example machine-readable instructions and/or perform the example operations of FIGS. 3 and 4 to implement the power management unit circuitry of FIG. 2.

FIG. 7 is a block diagram of an example implementation of the programmable circuitry of FIG. 6.

FIG. 8 is a block diagram of another example implementation of the programmable circuitry of FIG. 6.

FIG. 9 is a block diagram of an example software/firmware/instructions distribution platform (e.g., one or more servers) to distribute software, instructions, and/or firmware (e.g., corresponding to the example machine-readable instructions of FIGS. 3 and 4) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale.

### DETAILED DESCRIPTION

In compute platforms, memory and/or storage can be implemented according to a variety of standards. For example, memory and/or storage can communicate with a programmable circuit of a compute platform according to any type of memory interface standard, such as a Joint Electron Device Engineering Council (JEDEC) standard. Example JEDEC standards include double data rate (DDR) standards such as DDR, DDR2, DDR3, DDR4, DDR5, and DDR6. Additional or alternative DDR standards include multiplexed-rank DIMM (MRDIMM) standards and mobile DDR (MDDR) standards such as low power DDR (LPDDR), LPDDR2, LPDDR3, LPDDR4, LPDDR5, LPDDR6, etc. DDR standards also include graphics DDR (GDDR) standards such as GDDR, GDDR2, GDDR3, GDDR4, GDDR5, and GDDR6. In some examples, the memory interface standard is a RAMBUS® standard such as extreme data rate (XDR) or XDR2.

Additionally, memory and/or storage can be implemented according to a memory form factor such as the dual in-line memory module (DIMM) form factor. Other memory form factors are possible such as the universal DIMM (UniDIMM) form factor, the Accelerated Graphics Port (AGP) in-line memory module (AIMM) form factor, the compression attached memory module (CAMM) form factor, the single in-line memory module (SIMM) form factor, and/or the single in-line pin package (SIPP) form factor. DIMM form factor memory and/or storage can be implemented according to a variety of configurations of operating speed (measured in Hertz (Hz)). In some compute platforms (e.g., a server platform), some DIMM configurations exceed the power limit for a DIMM based on the limit set by a JEDEC standard.

For example, to comply with modem JEDEC standards, a DIMM cannot draw more than a certain power level when processing a workload (e.g., input power). That is, as a DIMM demands high power, precise control of power to the DIMM is relevant to regulate the power to a target power level. In modern JEDEC standards, the target power level for some DIMM architectures is 36 Watts (W). The 36 W input power level is an example based on a DIMM designed with three input power rails, each supporting 12 W. In other examples, a different input power level may be relevant. For example, if a DIMM is designed to have more input power rails or to support a larger input power, a different power level may be utilized. Tables 1-3 below illustrate example power draw for various DIMM configurations.

TABLE 1

| | Bandwidth | | Per-Rank | | | Power | Power | Power |
|---|---|---|---|---|---|---|---|---|
| | (gigabytes | | Capacity | Module | | Draw | Draw | Draw |
| DIMM | (GB) per | | (Gigabits | Capacity | | (W) | (W) | (W) |
| Type | second) | Module | (Gb)) | (GB) | | (85%) | (65%) | (50%) |
| MRDIMM | 12.8 | DRx8 | 16 Gb | 32 | GB | 18 | 15 | 13 |
| | | | 24 Gb | 48 | GB | 20 | 17 | 14 |
| | | | 32 Gb | 64 | GB | 22 | 19 | 16 |
| MRDIMM | 12.8 | QRx8 | 16 Gb | 64 | GB | 20 | 17 | 15 |
| | | | 24 Gb | 96 | GB | 22 | 19 | 17 |
| | | | 32 Gb | 128 | GB | 26 | 22 | 20 |
| MRDIMM | 12.8 | DRx4 | 16 Gb | 64 | GB | 28 | 23 | 20 |
| | | | 24 Gb | 96 | GB | 31 | 26 | 22 |
| | | | 32 Gb | 128 | GB | 30 | 25 | 22 |
| MRDIMM | 12.8 | QRx4 | 16 Gb | 128 | GB | 32 | 27 | 24 |
| | | | 24 Gb | 192 | GB | 35 | 31 | 28 |
| | | | 32 Gb | 256 | GB | 36.4 | 32 | 29 |

Table 1 depicts various configurations of MRDIMM having an upper bandwidth threshold of 12.8 gigabytes (GB) per second (GB/s). For example, the MRDIMM configurations of Table 1 are capable of operating at a bandwidth of less than or equal to 12.8 GB/s. In Table 1, the MRDIMM configurations are categorized based on module type designated by memory rank. Memory rank refers to the number of Dynamic Random Access Memory (DRAM) chips connected to same chip select signal in a module. For example, a dual-rank (DR) module includes two DRAM chips connected to the same chip select signal and a quad-rank (QR) module includes four DRAM chips connected to the two chip select signals where two DRAM chips are connected to each chip select signal. Example module types represented in Table 1 include an eight DR module, an eight QR module, a four DR module, and a four QR module.

Each MRDIMM module type in Table 1 is further categorized based on the per-rank capacity in gigabits (Gb). Example per-rank capacities represented in Table 1 include 16 Gb, 24 Gb, and 32 Gb. Table 1 also illustrates the power in W drawn by the various MRDIMM configurations at 50%, 65%, and 85% of the bandwidth. In Table 1, the MRDIMM configuration (bolded) of a four QR module having a per-rank capacity of 32 Gb and a module capacity of 256 GB draws 36.4 W at 85% bandwidth and therefore exceeds the 36 W limit described above.

TABLE 2

| | Bandwidth | | Per-Rank | | | Power | Power | Power |
|---|---|---|---|---|---|---|---|---|
| | (gigabytes | | Capacity | Module | | Draw | Draw | Draw |
| DIMM | (GB) per | | (Gigabits | Capacity | | (W) | (W) | (W) |
| Type | second) | Module | (Gb)) | (GB) | | (85%) | (65%) | (50%) |
| MRDIMM | 14.4 | DRx8 | 16 Gb | 32 | GB | 19 | 16 | 14 |
| | | | 24 Gb | 48 | GB | 22 | 18 | 15 |
| | | | 32 Gb | 64 | GB | 24 | 20 | 17 |
| MRDIMM | 14.4 | QRx8 | 16 Gb | 64 | GB | 21 | 18 | 16 |
| | | | 24 Gb | 96 | GB | 24 | 20 | 18 |
| | | | 32 Gb | 128 | GB | 27 | 24 | 21 |
| MRDIMM | 14.4 | DRx4 | 16 Gb | 64 | GB | 30 | 25 | 21 |
| | | | 24 Gb | 96 | GB | 33 | 28 | 23 |
| | | | 32 Gb | 128 | GB | 32 | 27 | 23 |
| MRDIMM | 14.4 | QRx4 | 16 Gb | 128 | GB | 34 | 29 | 25 |
| | | | 24 Gb | 192 | GB | 38 | 33 | 29 |
| | | | 32 Gb | 256 | GB | 39 | 34 | 30 |

Table 2 depicts various configurations of MRDIMM having an upper bandwidth threshold of 14.4 GB/s. For example, the MRDIMM configurations of Table 2 are capable of operating at a bandwidth of less than or equal to 14.4 GB/s. Table 2 includes similar configuration categories to Table 1. In Table 2, the MRDIMM configurations (bolded) of a four QR module having a per-rank capacity of 24 Gb and 32 Gb and a module capacity of 192 GB and 256 GB draws 38 W and 39 W, respectively, at 85% bandwidth and therefore exceeds the 36 W limit described above.

TABLE 3

| | Bandwidth | | Per-Rank | | | Power | Power | Power |
|---|---|---|---|---|---|---|---|---|
| | (gigabytes | | Capacity | Module | | Draw | Draw | Draw |
| DIMM | (GB) per | | (Gigabits | Capacity | | (W) | (W) | (W) |
| Type | second) | Module | (Gb)) | (GB) | | (85%) | (65%) | (50%) |
| MRDIMM | 16.0 | DRx8 | 16 Gb | 32 | GB | 21 | 17 | 15 |
| | | | 24 Gb | 48 | GB | 23 | 19 | 16 |
| | | | 32 Gb | 64 | GB | 25 | 21 | 18 |
| MRDIMM | 16.0 | QRx8 | 16 Gb | 64 | GB | 23 | 19 | 17 |
| | | | 24 Gb | 96 | GB | 25 | 21 | 19 |
| | | | 32 Gb | 128 | GB | 29 | 25 | 22 |
| MRDIMM | 16.0 | DRx4 | 16 Gb | 64 | GB | 33 | 27 | 23 |
| | | | 24 Gb | 96 | GB | 36 | 30 | 25 |
| | | | 32 Gb | 128 | GB | 34 | 29 | 25 |
| MRDIMM | 16.0 | QRx4 | 16 Gb | 128 | GB | 37 | 31 | 27 |
| | | | 24 Gb | 192 | GB | 40 | 35 | 30 |
| | | | 32 Gb | 256 | GB | 41 | 36 | 31 |

Table 3 depicts various configurations of MRDIMM having an upper bandwidth threshold of 16.0 GB/s. For example, the MRDIMM configurations of Table 3 are capable of operating at a bandwidth of less than or equal to 16.0 GB/s. Table 3 includes similar configuration categories to Tables 1 and 2. In Table 3, the MRDIMM configurations (bolded) of a four QR module having a per-rank capacity of 24 Gb and 32 Gb and a module capacity of 192 GB and 256 GB draws 40 W and 41 W, respectively, at 85% bandwidth and therefore exceeds the 36 W limit described above.

DIMMs include a power management integrated circuit (PMIC) (also referred to as a power management circuit) to control power delivered to the DRAMs of a DIMM. For example, a PMIC of a DIMM is implemented within the form factor of the DIMM (e.g., on-DIMM) and generates one or more supply voltages and/or one or more supply currents for DRAMs of the DIMM. Generally, on-DIMM PMICs are not designed to handle power exceeding the 36 W limit described above. Even if on-DIMM PMICs were capable of handling power exceeding the 36 W limit described above, a compute platform within which the DIMM is implemented would not be able to sustain excessive power (e.g., exceeding the 36 W limit) for all supported DIMM configurations. For example, the values for power represented in Tables 1-3 are based on estimated workloads and the usage of a DIMM for an actual workload may consume more (or less) power.

To protect a compute platform and avoid causing excessive failures (e.g., of on-DIMM PMICs, of interfaces with DIMMs, etc.), one approach would be for the compute platform not to support DIMM configurations that exceed the 36 W limit described above. However, this approach is not conducive to modern applications that utilize a variety of DIMM configurations including those that exceed the 36 W limit. For example, by not supporting DIMM configurations that exceed the 36 W limit, the amount of memory supported by a compute platform is limited.

If exceeding DIMM configurations are supported, another approach to protect a compute platform and avoid causing excessive failures would be to statically limit the bandwidth of DIMM configurations that exceed the 36 W limit. For example, if a DIMM of a compute platform will consume more than 36 W of power, the bandwidth of all DIMMs of the compute platform is limited to a set bandwidth below the level that would cause the DIMM to draw power exceeding the 36 W limit.

To statically limit the bandwidth of all DIMMs, this approach utilizes one sensor per voltage regulator (VR) where an individual VR supplies multiple DIMMs. However, due to variations in process, location, load, etc. not all DIMMs supported by the VR will be at the same power level. For example, there may be multiple DIMMs per memory channel and each DIMM may draw a separate amount of power. As such, relying on one VR sensor that monitors multiple DIMMs does not provide precision to monitor each DIMM when multiple DIMMs are implemented per channel. Additional sensors could be added to a compute platform to monitor per-DIMM activity, but doing so would increase the routing complexity, monetary cost, and area consumed on a substrate (e.g., a printed circuit board, a semiconductor substrate, etc.).

Furthermore, because an individual VR sensor does not provide per-DIMM monitoring, statically limiting the bandwidth to all DIMMs based on reading from an individual VR sensor will not be feasible as DIMM capacity increases and DIMM access time decreases. For example, as DIMM capacity increases and DIMM access time decreases, there will be a lower margin between when a DIMM exceeds a power limit and when the DIMM fails (or is deemed to have failed). For example, a DIMM could exceed the power limit before the VR sensor can detect the power spike.

As described above, when statically limiting bandwidth, the bandwidth of all DIMMs in a compute platform is throttled, even when only some DIMMs could be causing increase in the average power drawn (e.g., the noisy neighbor problem in DRAM). As such, statically limiting bandwidth is not conducive to modern applications. For example, at least because statically limiting bandwidth limits the bandwidth of memory of a compute platform to a lower level than that which the memory is capable of handling, statically limiting bandwidth does not support larger bandwidths utilized in modern applications.

Examples disclosed herein allow DIMM configurations that would otherwise exceed the power limit set by a JEDEC standard to operate at a higher average bandwidth than other approaches while also remaining below the power limit. To protect against exceeding a power limit of a compute platform, examples disclosed herein monitor the power level of each DIMM of the compute platform. For example, disclosed methods, apparatus, and articles of manufacture monitor power consumption per-DIMM via on-DIMM PMIC power registers.

That is, the input power to an on-DIMM PMIC is a proxy for the power consumed by the DIMM. As such, by inferring input power to an on-DIMM PMIC based on the output power from the on-DIMM PMIC (e.g., monitored by the on-DIMM PMIC power registers), examples disclosed herein infer the power consumed by the DIMM. If the power level of a DIMM is within a threshold of the power limit, examples disclosed herein throttle the bandwidth of the individual DIMM to reduce the power level drawn by that DIMM. As such, examples disclosed herein support a variety of DIMM configurations, such as those listed in Tables 1-3, by managing the peak power level on a per-DIMM basis, per workload.

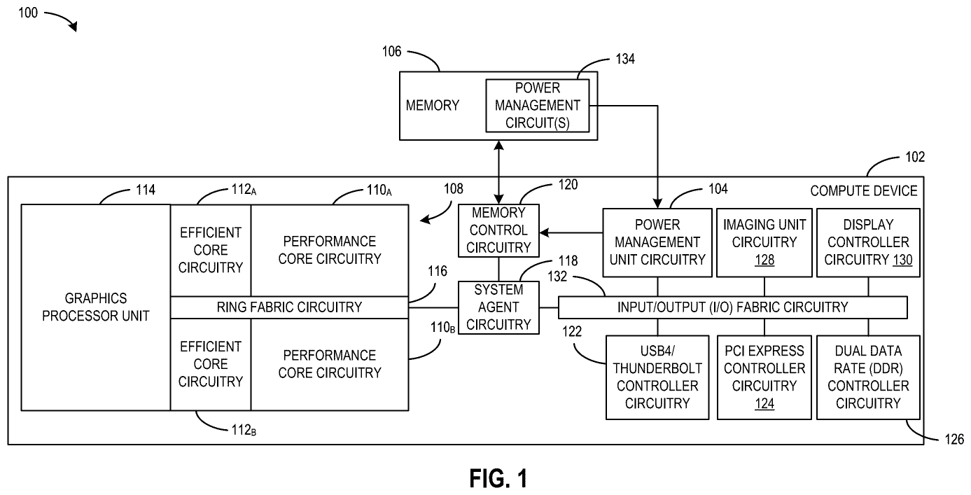

FIG. 1 is a block diagram of an example compute platform 100 in which an example compute device 102 includes example power management unit (PMU) circuitry 104 to throttle bandwidth between the compute device 102 and example memory 106 on a per-memory instance basis. In the example of FIG. 1, the compute device 102 includes example programmable circuitry 108. The example programmable circuitry 108 of FIG. 1 includes a first example performance core circuitry 110A, a second example performance core circuitry 110B, a first example efficient core circuitry 112A, a second example efficient core circuitry 112B, and an example graphics processor unit (GPU) 114.

In the illustrated example of FIG. 1, the first performance core circuitry 110A and the second performance core circuitry 110B are high-performance processor cores designed to process data quickly while maintaining performance efficiency. In the example of FIG. 1, the first efficient core circuitry 112A and the second efficient core circuitry 112B are designed for increased performance on smaller (e.g., background) tasks. For example, one or more of the first efficient core circuitry 112A or the second efficient core circuitry 112B can work in concert with one or more of the first performance core circuitry 110A or the second performance core circuitry 110B to accelerate core-intensive tasks (e.g., when rendering video).

In the illustrated example of FIG. 1, the first performance core circuitry 110A and the second performance core circuitry 110B are physically larger than the first efficient core circuitry 112A and the second efficient core circuitry 112B. For example, each of the first efficient core circuitry 112A and the second efficient core circuitry 112B is physically smaller than a performance core, with multiple efficient cores being capable of fitting into the physical space of one performance core. In the example of FIG. 1, the first performance core circuitry 110A, the second performance core circuitry 110B, the first efficient core circuitry 112A, the second efficient core circuitry 112B, and the GPU 114 are in communication via example ring fabric circuitry 116. The ring fabric circuitry 116 of FIG. 1 provides a data fabric interface between the various compute circuitry of the compute device 102, last-level cache, and die-to-die interface(s).

In the illustrated example of FIG. 1, the compute device 102 includes example system agent circuitry 118, example memory control circuitry 120, and one or more I/O controllers. For example, the one or more I/O controllers allow the programmable circuitry 108 to access one or more communication interfaces through respective I/O ports. In the example of FIG. 1, the one or more I/O controllers include example USB4® and/or Thunderbolt™ controller circuitry 122, example PCIe® controller circuitry 124, example DDR controller circuitry 126, example imaging unit circuitry 128, and example display controller circuitry 130.

In the illustrated example of FIG. 1, the example system agent circuitry 118 interfaces with the last-level cache and is responsible for managing cache coherency. For example, in a multi-level cache hierarchy, last-level cache refers to the last level of cache before a programmable circuit accesses the memory 106 of the compute platform 100. Additionally, the system agent circuitry 118 manages one or more internal and/or external point-to-point processor interconnect links with the compute device 102.

In the illustrated example of FIG. 1, the memory control circuitry 120 controls memory access requests to the memory 106 by the programmable circuitry 108. For example, the memory control circuitry 120 is implemented by hardware (e.g., a chiplet, one or more tiles, etc.) in accordance with any type of memory interface standard, such as a JEDEC standard. Example JEDEC standards include DDR standards such as DDR, DDR2, DDR3, DDR4, DDR5, and DDR6. Additional or alternative DDR standards include MRDIMM standards and MDDR standards such as LPDDR, LPDDR2, LPDDR3, LPDDR4, LPDDR5, LPDDR6, etc. DDR standards also include GDDR standards such as GDDR, GDDR2, GDDR3, GDDR4, GDDR5, and GDDR6. In some examples, the memory interface standard is a RAMBUS® standard such as XDR or XDR2.

In the illustrated example of FIG. 1, the memory 106 includes one or more instances of memory. For example, the memory 106 is implemented by a volatile memory (e.g., a Synchronous DRAM (SDRAM), DRAM, RAMBUS® DRAM (RDRAM), etc.) and/or a non-volatile memory (e.g., flash memory). The memory 106 may additionally or alternatively be implemented by one or more mass storage devices such as hard disk drive(s) (HDD(s)), compact disk (CD) drive(s), digital versatile disk (DVD) drive(s), solid-state disk (SSD) drive(s), Secure Digital (SD) card(s), CompactFlash (CF) card(s), etc. While in the illustrated example the memory 106 is illustrated as a single memory, the memory 106 may be implemented by multiple memories. In additional or alternative examples, the memory 106 may be implemented by any number and/or type(s) of memories. Furthermore, the data stored in the memory 106 may be in any data format such as, for example, binary data, comma delimited data, tab delimited data, Structured Query Language (SQL), structures, etc.

In the illustrated example of FIG. 1, the memory 106 is implemented externally to the compute device 102. In some examples, the memory 106 is implemented internal to the compute device 102 (e.g., as one or more chiplets and/or one or more tiles). In the example of FIG. 1, the memory 106 is implemented in accordance with a memory interface standard such as a JEDEC standard (e.g., a DDR standard, an MRDIMM standard, an mDDR standard, a GDDR standard, etc.) and/or a RAMBUS® standard (e.g., an XDR standard). Additionally, the memory 106 is implemented in accordance with a memory form factor such as the DIMM form factor. Other memory form factors are possible such as the UniDIMM form factor, the AIMM form factor, the CAMM form factor, the SIMM form factor, and/or the SIPP form factor.

As described herein, the memory 106 supports a multi-channel interface between the memory 106 and the compute device 102. For example, a memory channel refers to a communication path between the memory 106 and the compute device 102. In the example of FIG. 1, the memory 106 supports a quad-channel architecture. Increasing the number of channels increases the data rate of communication between the memory 106 and the compute device 102. Additional or alternative architectures may also be supported by the memory 106 such as a dual-channel architecture, a triple-channel architecture, a hexa-channel architecture, an octa-channel architecture, or a dodeca-channel architecture.

In the illustrated example of FIG. 1, the USB4® and/or Thunderbolt™ controller circuitry 122 facilitates communication between the compute device 102 and a USB4®-connected and/or Thunderbolt™-connected device. In the example of FIG. 1, the PCIe® controller circuitry 124 facilitates communication between the compute device 102 and a PCIe®-connected device. Also, in the example of FIG. 1, the DDR controller circuitry 126 facilitates communication between the compute device 102 and a DDR memory. For example, the DDR controller circuitry 126 formats data access requests to DDR memory and forwards the data access requests to the memory control circuitry 120.

In the illustrated example of FIG. 1, the imaging unit circuitry 128 facilitates communication between the compute device 102 and an imaging device (e.g., a camera). Also, in the example of FIG. 1, the display controller circuitry 130 facilitates communication between the compute device 102 and a display device (e.g., a monitor). In the example of FIG. 1, the compute device 102 includes example input/output (I/O) fabric circuitry 132 that provides a data fabric interface between the various compute circuitry of the compute device 102 and the PMU circuitry 104 and/or one or more I/O controllers of the compute device 102.

As described above, the PMU circuitry 104 throttles bandwidth between the compute device 102 and the memory 106 on a per-memory instance basis. For example, the PMU circuitry 104 monitors per-memory instance (e.g., per-DIMM) power consumption and controls power consumption per-memory instance (e.g., per-DIMM). As such, the PMU circuitry 104 prevents any memory instances from consuming a level of power that exceeds a power limit set by a JEDEC standard (e.g., for a length of time that would damage the memory instance). For example, the PMU circuitry 104 avoids the noisy neighbor problem that occurs in DRAM as different DIMMs consume different amounts of power.

In the illustrated example of FIG. 1, as memory instances (e.g., DIMMs) consume more power, the PMU circuitry 104 throttles the bandwidth of each instance of memory individually and does not throttle the bandwidth to all instances of the memory 106 (e.g., not all DIMMs) as a group. For example, each instance of the memory 106 includes an example power management circuit 134 from which the PMU circuitry 104 reads the output power and/or the output current from the power management circuit 134. In the example of FIG. 1, the power management circuit 134 controls power delivered to one or more DRAMs of each instance of the memory 106.

For example, the power management circuit 134 generates one or more supply voltages and/or one or more supply currents for DRAMs of an instance of the memory 106. As used herein, the power drawn by the power management circuit 134 to generate the one or more supply voltages and/or the one or more supply currents is referred to as an input power to the power management circuit 134. Additionally, as used herein, the power produced by the power management circuit 134 to supply the DRAMs of an instance of the memory 106 is referred to as an output power from the power management circuit 134.

In the illustrated example of FIG. 1, the PMU circuitry 104 (e.g., a system-on-chip (SoC)) reads the output power and/or output current (e.g., the supply current provided by the power management circuit 134) registers from each instance of the power management circuit 134 through an improved inter-integrated circuit (I3C) bus. For example, the PMU circuitry 104 reads the output power and/or output current registers on a programmable interval and computes the input power to each instance of the power management circuit 134. After multiple readouts (e.g., to determine an average of power over a programable interval), the PMU circuitry 104 determines whether the input power to any instance of the power management circuit 134 exceeds (e.g., does not satisfy) a threshold power (e.g., a programmable value).

In the illustrated example of FIG. 1, if the PMU circuitry 104 determines that the power readout from an instance of the power management circuit 134 exceeds the threshold power, then the PMU circuitry 104 implements a control algorithm (e.g., an advanced control algorithm such as an artificial intelligence (AI)-based algorithm, a Proportional-Integral-Derivative (PID) control algorithm, etc.) as a feedback control loop to throttle the bandwidth to the memory 106. For example, the PMU circuitry 104 computes a bandwidth control setting for the memory 106 and provides the bandwidth control setting the memory control circuitry 120. In the example of FIG. 1, the memory control circuitry 120 acts an actuator and throttles the bandwidth of functional traffic (e.g., DDR5 traffic) to the memory 106. In this manner, the bandwidth control setting provided by the PMU circuitry 104 throttles the bandwidth of the memory 106 such that the input power to the power management circuit 134 reduces to satisfy the threshold power.

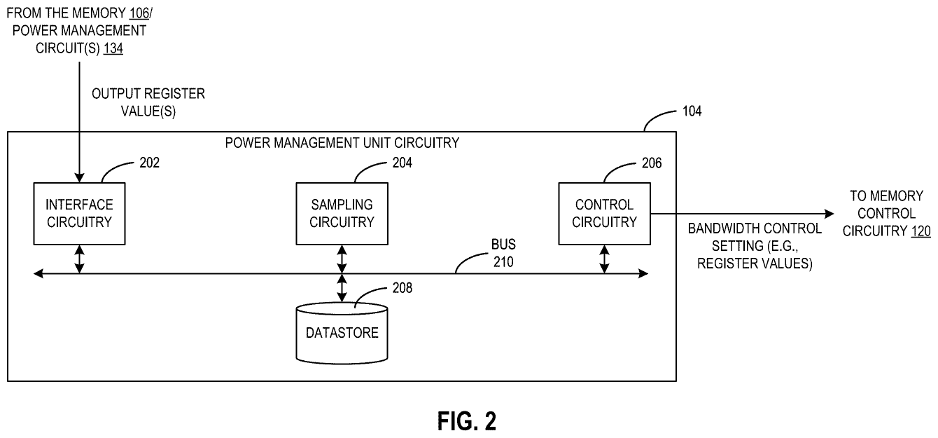

FIG. 2 is a block diagram of an example implementation of the PMU circuitry 104 of FIG. 1. In the example of FIG. 2, the PMU circuitry 104 includes example interface circuitry 202, example sampling circuitry 204, example control circuitry 206, and an example datastore 208. Also, in the example of FIG. 2, the interface circuitry 202, the sampling circuitry 204, the control circuitry 206, and/or the datastore 208 are in communication via an example communication bus 210.

The PMU circuitry 104 of FIG. 2 may be instantiated (e.g., creating an instance of, bring into being for any length of time, materialize, implement, etc.) by programmable circuitry. For example, programmable circuitry may be implemented by a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Additionally or alternatively, the PMU circuitry 104 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) (e.g., another form of programmable circuitry) structured and/or configured in response to execution of second instructions to perform operations corresponding to the first instructions.

It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

As described above, the interface circuitry 202, the sampling circuitry 204, the control circuitry 206, and/or the datastore 208 are in communication via the communication bus 210. For example, the communication bus 210 is a bus implemented in accordance with an interface standard or protocol such as an Inter-Integrated Circuit (I2C) bus, a serial peripheral interface (SPI) bus, an I3C bus, a Peripheral Component Interconnect (PCI) bus, a PCI Express (PCIe) bus, and/or a Compute Express Link (CXL) bus. Example CXL buses include the CXL buses for cache-coherent accesses to system memory (CXL.cache or CXL.$), the CXL bus for device memory (CXL.Mem), and the CXL bus for PCIe-based I/O devices (CXL.IO/PCIe). In some examples, the communication bus 210 is implemented as a die-to-die interconnect such as an embedded multi-die interconnect bridge (EMIB), a co-EMIB, a chip-on-wafer-on-substrate (CoWoS) interconnect, an integrated fan-out (InFO) interconnect, and/or an organic substrate-based interconnect.

In the illustrated example of FIG. 2, the interface circuitry 202 is coupled to one or more instances of the power management circuit 134 via a communication bus implemented in accordance with an interface standard or protocol. For example, the interface circuitry 202 is coupled to the power management circuit 134 via an I3C bus. Additionally or alternatively, the interface circuitry 202 is coupled to the power management circuit 134 via a communication bus is implemented by a communication bus implemented in accordance with another interface standard or protocol such as an Ethernet interface, a universal serial bus (USB) interface, a Bluetooth® interface, and/or a near field communication (NFC) interface. In some examples, the interface circuitry 202 communicates with the power management circuit 134 according to a die-to-die interconnect such as an EMIB, a co-EMIB, a high bandwidth memory (HBM) interconnect, a CoWoS interconnect, an InFO interconnect, and/or an organic substrate-based interconnect.

In the illustrated example of FIG. 2, the interface circuitry 202 reads one or more output registers of the power management circuit 134. For example, per instance of the memory 106 (e.g., per-DIMM), the power management circuit 134 includes three output registers corresponding to three supply rails provided by the power management circuit 134. In general, the power management circuit 134 includes one output register per supply rail provided by the power management circuit 134. In the example of FIG. 2, the one or more output registers of the power management circuit 134 store data representative of the output current and/or the output power from the power management circuit 134. Each output register of the power management circuit 134 is an 8-bit register that the power management circuit 134 updates on a programmable interval. For example, the power management circuit 134 updates each output register of the power management circuit 134 every 4 milliseconds (ms).

An example description of data stored in an output register of the power management circuit 134 is illustrated in Table 4 below. With reference to Table 4, the interface circuitry 202 reads the register 0x1C (e.g., “current power from DIMM”) of the power management circuit 134.

TABLE 4

| | R0C | | |
|---|---|---|---|
| Bits | Attribute | Default | Description |
| 7:0 | RO | 0 | ROC [7:0]: |
| | | | SWA_OUTPUT_CURRENT_POWER_MEASUREMENT |
| | | | If Table 112, “Register 0x1A”[1] = ‘0’: Switch Node A |
| | | | Output Current or Output Power Measurement |
| | | | 0000 0000 = Undefined |
| | | | 0000 0001 = 0.125 A or 0.125 W |
| | | | 0000 0010 = 0.25 A or 0.25 W |
| | | | 0000 0011 = 0.375 A or 0.375 W |
| | | | 0000 0100 = 0.5 A or 0.5 W |
| | | | ... |
| | | | 1111 1111 >= 31.875 A or 31.875 W |
| | | | If Table 112, “Register 0x1A”[1] = ‘1’: Sum of SWA, |
| | | | SWB, and SWC Output Power |
| | | | 0000 0000 = Undefined |
| | | | 0000 0001 = 0.125 W |
| | | | 0000 0010 = 0.25 W |
| | | | 0000 0011 = 0.375 W |
| | | | 0000 0100 = 0.5 W |
| | | | ... |
| | | | 1111 1111 >= 31.875 W |

In the illustrated example of FIG. 2, the interface circuitry 202 reads the one or more output registers of the power management circuit 134 on a programmable interval. For example, in FIG. 2, the interface circuitry 202 reads the three output registers (e.g., one per supply rail) of the power management circuit 134 and loads the contents of the three output registers into a register space of the sampling circuitry 204. In the example of FIG. 2, the register space of the sampling circuitry 204 is located in the datastore 208.

In some examples, the interface circuitry 202 reads one output register of the power management circuit 134. In such example, the power management circuit 134 is configured to combine the values of the three output registers into a single output register. As such, the interface circuitry 202 can read the value of the single output register and store the value in the register space of the sampling circuitry 204.

In the illustrated example of FIG. 2, the interface circuitry 202 reads the one or more output registers of the power management circuit 134 once every 128 ms. In some examples, the interface circuitry 202 reads the one or more output registers as quickly as once every 4 ms. As described above, the interval at which the interface circuitry 202 reads the one or more output registers of the power management circuit 134 is programmable. Per output register of the power management circuit 134, the interface circuitry 202 reads an output register in about 1 microsecond (μs). In some examples, the interface circuitry 202 reads an output register of the power management circuit 134 in a different amount of time. For example, depending on the design of the power management unit circuitry 104, the interface circuitry 202 may read an output register of the power management circuit 134 in a different amount of time. As described above, upon reading the one or more output registers of the power management circuit 134, the interface circuitry 202 writes the value(s) of the one or more output registers into the register space of the sampling circuitry 204.

In the illustrated example of FIG. 2, the sampling circuitry 204 is implemented by software and/or firmware executed and/or instantiated by programmable circuitry. In the example of FIG. 2, the sampling circuitry 204 accesses the value(s) of the one or more output registers. For example, the sampling circuitry 204 reads the value(s) from the register space of the sampling circuitry 204 in the datastore 208. In the example of FIG. 2, the sampling circuitry 204 determines the output power (e.g., total output power) from the power management circuit 134 based on the value(s) of the one or more output registers.

For example, if the interface circuitry 202 reads a single output register that stores data representative of output power from the power management circuit 134, the sampling circuitry 204 reads the value of the single output register written to the datastore 208 by the interface circuitry 202 to determine the output power. In some examples, if the interface circuitry 202 reads three output registers that store data representative of output power (e.g., per supply rail) from the power management circuit 134, the sampling circuitry 204 reads the three values from the datastore 208. In such examples, the sampling circuitry 204 adds the values of the three output registers (e.g., one per supply rail) to determine the output power from the power management circuit 134.

Additionally or alternatively, if the interface circuitry 202 reads a single output register that stores data representative of output current from the power management circuit 134, the sampling circuitry 204 reads the value of the single output register written to the datastore 208 by the interface circuitry 202 to determine the output current. Based on the output current, the sampling circuitry 204 computes the output power. For example, the sampling circuitry 204 computes the output power as the produce of a resistance and the square of the output current (e.g., P=RI² where R is a known value).

In some examples, if the interface circuitry 202 reads three output registers that store data representative of output current (e.g., per supply rail) from the power management circuit 134, the sampling circuitry 204 reads the three values from the datastore 208. In such examples, the sampling circuitry 204 adds the values of the three output registers (e.g., one per supply rail) to determine the output current from the power management circuit 134. Based on the output current, the sampling circuitry 204 computes the output power (e.g., P=RI² where R is a known value). In some examples, the order of operations is different (e.g., the sampling circuitry 204 determines the output power per supply rail and sums the output power per supply rail to determine the output power from the power management circuit 134).

In the illustrated example of FIG. 2, the sampling circuitry 204 determines an input power to the power management circuit 134 based on the output power from the power management circuit 134. For example, the power management circuit 134 generates voltages at and/or currents from the supply terminals of the power management circuit 134 based on the input power to the power management circuit 134. As such, the sampling circuitry 204 converts the output power from the power management circuit 134 into the input power to the power management circuit 134. For example, the sampling circuitry 204 divides the output power by a value (e.g., 0.9) indicative of the efficiency of the power management circuit 134 (e.g., 90%).

In the illustrated example of FIG. 2, the interface circuitry 202 reads the one or more output registers of the power management circuit 134 and the sampling circuitry 204 determines the input power to the power management circuit 134 multiple times over a programmable period. For example, the programmable period is between five and ten seconds in FIG. 2. In the example of FIG. 2, the sampling circuitry 204 determines a root-mean-square (RMS) input power and/or an average input power to the power management circuit 134 based on the multiple determinations of the input power over the programmable period. For example, the sampling circuitry 204 determines the RMS input power to the power management circuit 134 for the programmable interval according to Equation 1 below.

$${P}_{{IN}_{RMS}} = \sqrt{\frac{1}{n} ( {P}_{{IN}_{1}^{2}} + {P}_{{IN}_{2}^{2}} + … + {P}_{{IN}_{n}^{2}} )} \qquad Equation 1$$

In Equation 1, n represents the number of samples of input power determined by the sampling circuitry 204 over the programmable interval (e.g., 10 seconds/128 ms≈78 samples). For example, the sampling circuitry 204 stores values for samples of the input power to the power management circuit 134 in the datastore 208. In the example of FIG. 2, the sampling circuitry 204 provides the value of the input power to the control circuitry 206. For example, the sampling circuitry 204 provides the RMS input power and/or the average input power to the control circuitry 206.

In the illustrated example of FIG. 2, the control circuitry 206 is implemented by software and/or firmware executed and/or instantiated by programmable circuitry. In the example of FIG. 2, the control circuitry 206 implements a control algorithm such as a PID algorithm and/or an AI-based algorithm to determine whether the bandwidth of the memory 106 is to be throttled to reduce the input power drawn by the power management circuit 134. For example, the control circuitry 206 compares the RMS and/or average input power to an input power threshold (e.g., the 36 W JEDEC limit) to determine whether to throttle the bandwidth of the memory 106. As such, the control circuitry 206 can, in some examples, be referred to as artificial intelligence controller (e.g., a neural network controller) or a proportional, integral, derivative controller.

In the illustrated example of FIG. 2, if the RMS and/or average input power exceeds the input power threshold, then the control circuitry 206 determines a bandwidth control setting to provide to the memory control circuitry 120. In the example of FIG. 2, the control circuitry 206 determines a bandwidth control setting to provide to the memory control circuitry 120 on a programmable interval. For example, the control circuitry 206 determines a bandwidth control setting to provide to the memory control circuitry 120 once every 128 ms. In the example of FIG. 2, the control circuitry 206 determines a bandwidth control setting at least ten times faster than the programmable interval for determining RMS and/or average input power.

Thus, if the programmable interval for determining RMS and/or average input power is 5 seconds, then the control circuitry 206 determines a bandwidth control setting at least once every 0.5 seconds. Also, if the programmable interval for determining RMS and/or average input power is 10 seconds, then the control circuitry 206 determines a bandwidth control setting at least once every second. As such, in the example of FIG. 2, the control circuitry 206 determines a bandwidth control setting based on at least 10 RMS and/or average input power values. In general, the number of RMS and/or average input power values utilized to determine a bandwidth control setting is a programmable value.

In the illustrated example of FIG. 2, the PMU circuitry 104 includes the datastore 208 to record data (e.g., value(s) of one or more output registers of the power management circuit 134, value(s) for samples of the input power to the power management circuit 134, etc.). The datastore 208 may be implemented by a volatile memory (e.g., a SDRAM, DRAM, RDRAM, etc.) and/or a non-volatile memory (e.g., flash memory). The datastore 208 may additionally or alternatively be implemented by one or more DDR memories, such as DDR, DDR2, DDR3, DDR4, DDR5, mDDR, DDR SDRAM, etc. The datastore 208 may additionally or alternatively be implemented by one or more mass storage devices such as HDD(s), CD drive(s), DVD drive(s), SSD drive(s), SD card(s), CF card(s), etc. While in the illustrated example the datastore 208 is illustrated as a single datastore, the datastore 208 may be implemented by any number and/or type(s) of datastore. Furthermore, the data stored in the datastore 208 may be in any data format such as, for example, binary data, comma delimited data, tab delimited data, SQL structures, etc.

As described above, the PMU circuitry 104 individually adjusts the bandwidth to each instance of the memory 106. As such, the PMU circuitry 104 can determine respective input powers to power management circuits for instances of the memory 106 that are on a same channel and cause the memory control circuitry 120 to adjust respective bandwidths to the instances of the memory 106 on the same channel. In additional or alternative examples, multiple instances of the memory 106 are grouped together for purposes of workload interleaving. For example, four instances of the memory 106 are grouped together into a cluster also referred to as a quadrant. In such examples, the PMU circuitry 104 adjusts the bandwidth to each cluster (e.g., quadrant) of instances of the memory 106 based on the average input power to the cluster (e.g., quadrant) of instances of the memory 106.

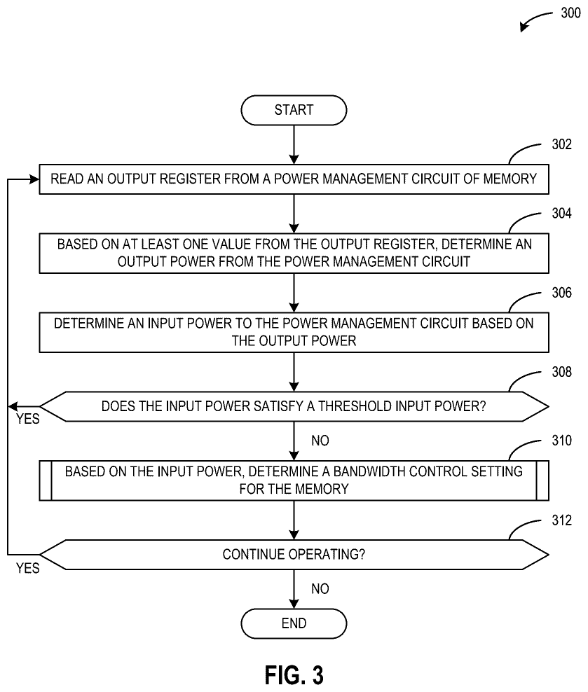

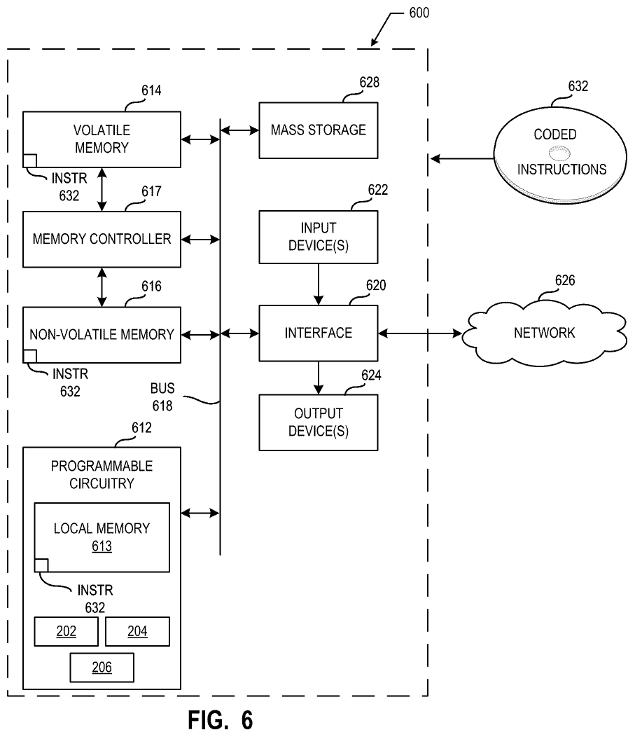

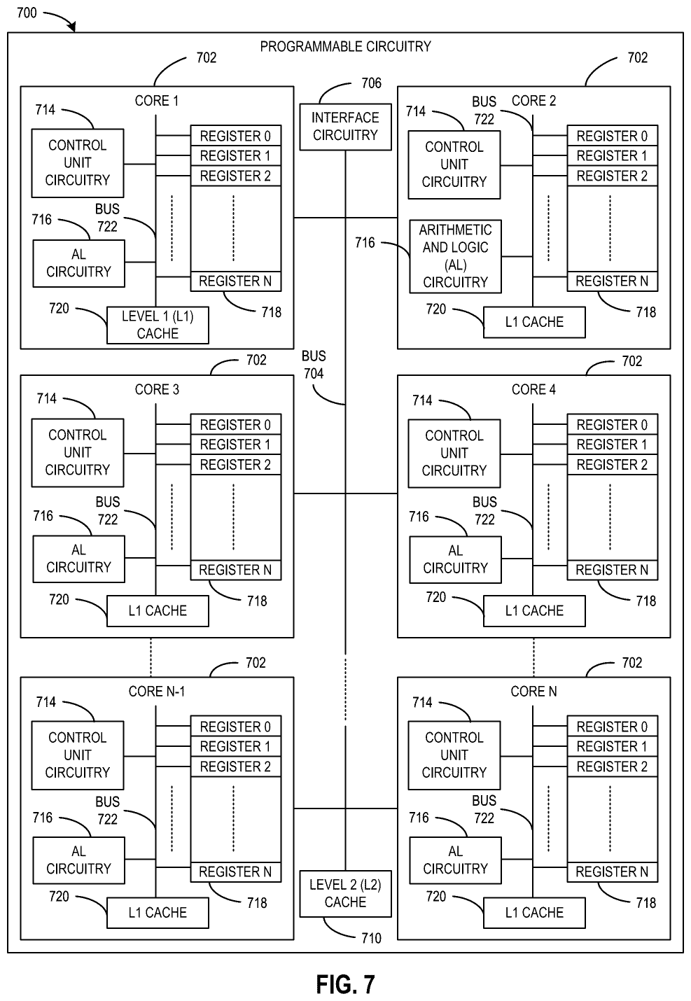

In some examples, the interface circuitry 202 is instantiated by programmable circuitry executing interfacing instructions and/or configured to perform operations such as those represented by the flowchart(s) of FIG. 3. In some examples, the PMU circuitry 104 includes means for accessing at least one output register. For example, the means for accessing may be implemented by the interface circuitry 202. In some examples, the interface circuitry 202 may be instantiated by programmable circuitry such as the example programmable circuitry 612 of FIG. 6. For instance, the interface circuitry 202 may be instantiated by the example microprocessor 700 of FIG. 7 executing machine-executable instructions such as those implemented by at least block 302 of FIG. 3.

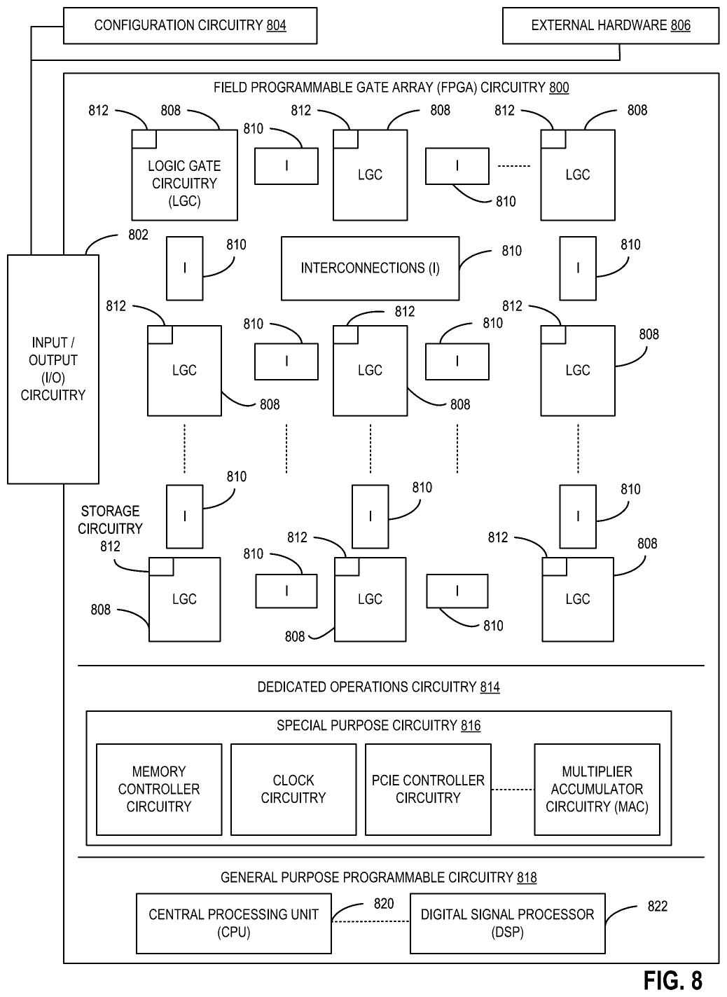

In some examples, the interface circuitry 202 may be instantiated by hardware logic circuitry, which may be implemented by an ASIC, XPU, or the FPGA circuitry 800 of FIG. 8 configured and/or structured to perform operations corresponding to the machine-readable instructions. Additionally or alternatively, the interface circuitry 202 may be instantiated by any other combination of hardware, software, and/or firmware. For example, the interface circuitry 202 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

In some examples, the sampling circuitry 204 is instantiated by programmable circuitry executing sampling instructions and/or configured to perform operations such as those represented by the flowchart(s) of FIG. 3. In some examples, the PMU circuitry 104 includes means for determining an input power to a power management circuit. For example, the means for determining may be implemented by the sampling circuitry 204. In some examples, the sampling circuitry 204 may be instantiated by programmable circuitry such as the example programmable circuitry 612 of FIG. 6. For instance, the sampling circuitry 204 may be instantiated by the example microprocessor 700 of FIG. 7 executing machine-executable instructions such as those implemented by at least blocks 304, 306, and 312 of FIG. 3.

In some examples, the sampling circuitry 204 may be instantiated by hardware logic circuitry, which may be implemented by an ASIC, XPU, or the FPGA circuitry 800 of FIG. 8 configured and/or structured to perform operations corresponding to the machine-readable instructions. Additionally or alternatively, the sampling circuitry 204 may be instantiated by any other combination of hardware, software, and/or firmware. For example, the sampling circuitry 204 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

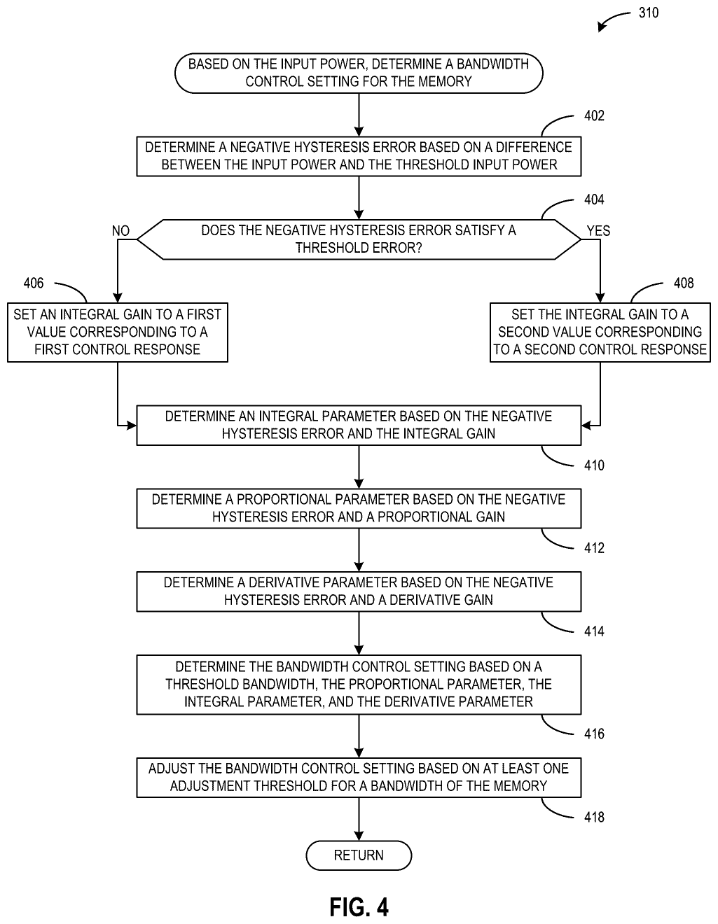

In some examples, the control circuitry 206 is instantiated by programmable circuitry executing bandwidth controlling instructions and/or configured to perform operations such as those represented by the flowchart(s) of FIGS. 3 and 4. In some examples, the PMU circuitry 104 includes means for adjusting a bandwidth control setting of memory. For example, the means for adjusting may be implemented by the control circuitry 206. In some examples, the control circuitry 206 may be instantiated by programmable circuitry such as the example programmable circuitry 612 of FIG. 6. For instance, the control circuitry 206 may be instantiated by the example microprocessor 700 of FIG. 7 executing machine-executable instructions such as those implemented by at least blocks 308 and 310 of FIG. 3 and/or at least blocks 402, 404, 406, 408, 410, 412, 414, 416, and 418 of FIG. 4.

In some examples, the control circuitry 206 may be instantiated by hardware logic circuitry, which may be implemented by an ASIC, XPU, or the FPGA circuitry 800 of FIG. 8 configured and/or structured to perform operations corresponding to the machine-readable instructions. Additionally or alternatively, the control circuitry 206 may be instantiated by any other combination of hardware, software, and/or firmware. For example, the control circuitry 206 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

While an example manner of implementing the PMU circuitry 104 of FIG. 1 is illustrated in FIG. 2, one or more of the elements, processes, and/or devices illustrated in FIG. 2 may be combined, divided, re-arranged, omitted, eliminated, and/or implemented in any other way. Further, the example interface circuitry 202, the example sampling circuitry 204, the example control circuitry 206, and/or, more generally, the example PMU circuitry 104 of FIG. 2, may be implemented by hardware alone or by hardware in combination with software and/or firmware. Thus, for example, any of the example interface circuitry 202, the example sampling circuitry 204, the example control circuitry 206, and/or, more generally, the example PMU circuitry 104 of FIG. 2, could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine-readable instructions (e.g., firmware or software). Further still, the example PMU circuitry 104 of FIG. 2 may include one or more elements, processes, and/or devices in addition to, or instead of, those illustrated in FIG. 2, and/or may include more than one of any or all of the illustrated elements, processes, and devices.

Flowchart(s) representative of example machine-readable instructions, which may be executed by programmable circuitry to implement and/or instantiate the PMU circuitry 104 of FIG. 2 and/or representative of example operations which may be performed by programmable circuitry to implement and/or instantiate the PMU circuitry 104 of FIG. 2, are shown in FIGS. 3 and 4. The machine-readable instructions may be one or more executable programs or portion(s) of one or more executable programs for execution by programmable circuitry such as the programmable circuitry 612 shown in the example programmable circuitry platform 600 discussed below in connection with FIG. 6 and/or may be one or more function(s) or portion(s) of functions to be performed by the example programmable circuitry (e.g., an FPGA) discussed below in connection with FIGS. 7 and/or 8. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer-readable and/or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer-readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer-readable storage medium may include one or more mediums. Further, although the example program is described with reference to the flowchart(s) illustrated in FIGS. 3 and 4, many other methods of implementing the example PMU circuitry 104 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, a CPU, a GPU, a VPU, and/or an FPGA. The programmable circuitry may include one or more CPUs, one or more GPUs, one or more VPUs, and/or one or more FPGAs located in the same package (e.g., the same integrated circuit (IC) package or in two or more separate housings), one or more CPUs, GPUs, VPUs, and/or one or more FPGAs in a single machine, multiple CPUs, GPUs, VPUs, and/or FPGAs distributed across multiple servers of a server rack, and/or multiple CPUs, GPUs, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine-executable instructions. For example, the machine-readable instructions may be fragmented and stored on one or more storage devices, disks, and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of computer-executable and/or machine-executable instructions that implement one or more functions and/or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine-readable, computer-readable, and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 3 and 4 may be implemented using executable instructions (e.g., computer-readable and/or machine-readable instructions) stored on one or more non-transitory computer-readable and/or machine-readable media. As used herein, the terms non-transitory computer-readable medium, non-transitory computer-readable storage medium, non-transitory machine-readable medium, and/or non-transitory machine-readable storage medium are expressly defined to include any type of computer-readable storage device and/or storage disk and to exclude propagating signals and to exclude transmission media. Examples of such non-transitory computer-readable medium, non-transitory computer-readable storage medium, non-transitory machine-readable medium, and/or non-transitory machine-readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer-readable storage device” and “non-transitory machine-readable storage device” are defined to include any physical (mechanical, magnetic, and/or electrical) hardware to retain information for a time period, but to exclude propagating signals and to exclude transmission media. Examples of non-transitory computer-readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer-readable instructions, machine-readable instructions, etc., and/or manufactured to execute computer-readable instructions, machine-readable instructions, etc.

FIG. 3 is a flowchart representative of example machine-readable instructions and/or example operations 300 that may be executed, instantiated, and/or performed by example programmable circuitry to implement the PMU circuitry 104 of FIG. 2. The example machine-readable instructions and/or the example operations 300 of FIG. 3 begin at block 302, at which the interface circuitry 202 reads an output register from the power management circuit 134 of the memory 106. At block 304, based on at least one value from the output register, the sampling circuitry 204 determines an output power from the power management circuit 134.

In the illustrated example of FIG. 3, at block 306, the sampling circuitry 204 determines an input power to the power management circuit 134 based on the output power. For example, the sampling circuitry 204 determines the input power to the power management circuit 134 during a first interval of time. In the example of FIG. 3, the sampling circuitry 204 determines the input power as a running average of the input power to the power management circuit 134. For example, the sampling circuitry 204 determines the running average of the input power to the power management circuit 134 based on the power readout from the power management circuit 134. In this manner, the sampling circuitry 204 smooths out instantaneous jumps in the power readout from the power management circuit 134. At block 308, the control circuitry 206 determines whether the input power satisfies a threshold input power. For example, the control circuitry 206 determines a difference between the input power and the threshold input power and if the difference is zero, the control circuitry 206 implicitly determines that the input power satisfies the threshold input power. In the example of FIG. 3, the threshold input power is a programmable value (e.g., 36 W).

In the illustrated example of FIG. 3, based on (e.g., in response to) the control circuitry 206 determining that the input power satisfies the threshold input power (block 308: YES), the machine-readable instructions and/or the operations 300 return to block 302. Based on (e.g., in response to) the control circuitry 206 determining that the input power does not satisfy the threshold input power (block 308: NO), the machine-readable instructions and/or the operations 300 proceed to block 310. At block 310, based on the input power, the control circuitry 206 determines a bandwidth control setting for the memory 106. For example, the control circuitry 206 determines a bandwidth control setting for the memory 106 to cause the input power to the power management circuit 134 to satisfy (e.g., be less than the threshold input power) during a second interval of time.

In the illustrated example of FIG. 3, at block 312, the sampling circuitry 204 determines whether to continue operating. Based on (e.g., in response to) the sampling circuitry 204 determining to continue operating (block 312: YES), the machine-readable instructions and/or the operations 300 return to block 302. Based on (e.g., in response to) the sampling circuitry 204 determining not to continue operating (block 312: NO), the machine-readable instructions and/or the operations 300 terminate.

FIG. 4 is a flowchart representative of example machine-readable instructions and/or example operations 310 that may be executed, instantiated, and/or performed by example programmable circuitry to implement the control circuitry 206 of FIG. 2. For example, the machine-readable instructions and/or operations 310 of FIG. 4 correspond to a PID implementation of the control circuitry 206. In the example of FIG. 4, the control circuitry 206 operates based on the input power to the power management circuit 134.

For example, the control circuitry 206 determines the RMS input power according to Equation 2 below.

$${P}_{{IN}_{{RMS}_{NEXT}}} = \sqrt{\frac{{{P}_{{IN}_{RMS \_ PREV}}}^{2} * ( N - dt ) + {{P}_{{IN}_{RMS}}}^{2} * dt}{N}} \qquad Equation 2$$

In Equation 2, Nis the programmable interval across which RMS input power is determined (e.g., 10 seconds) and dt is the sampling rate of the control circuitry 206 (e.g., 128 ms). As described above, the sampling circuitry 204 determines P_{IN}_{_{RMS}} according to Equation 1 above. As shown in Equation 2, the control circuitry 206 filters input power samples provided by the sampling circuitry 204. In the example of FIG. 4, the example machine-readable instructions and/or the example operations 310 of FIG. 3 begin at block 402, at which the control circuitry 206 determines a negative hysteresis error based on a difference between the input power and the threshold input power.

For example, the control circuitry 206 applies a negative hysteresis setting to the difference between the input power (determined according to Equation 2) and the threshold input power to determine the negative hysteresis error. In the example of FIG. 4, the negative hysteresis setting is an offset to regulate how quickly the control circuitry 206 adjusts the bandwidth control setting for the memory 106. For example, the negative hysteresis setting is a programmable value. In the example of FIG. 4, at block 404, the control circuitry 206 determines whether the negative hysteresis error satisfies a threshold error.

In the illustrated example of FIG. 4, the control circuitry 206 determines whether the negative hysteresis error is less than or equal to zero. Based on (e.g., in response to) the control circuitry 206 determining that the negative hysteresis error does not satisfy the threshold error (block 404: NO), the machine-readable instructions and/or the operations 310 proceed to block 406. At block 406, the control circuitry 206 sets an integral gain to a first value corresponding to a first control response. For example, the first control response is a fast response to cause the bandwidth of the memory 106 to quickly reduce which reduces the input power to the power management circuit 134 quickly.

Based on (e.g., in response to) the control circuitry 206 determining that the negative hysteresis error satisfies the threshold error (block 404: YES), the machine-readable instructions and/or the operations 310 proceed to block 408. At block 408, the control circuitry 206 sets the integral gain to a second value corresponding to a second control response. For example, the second control response is a slow response to cause the bandwidth of the memory 106 to slowly reduce which reduces the input power to the power management circuit 134 slowly.

In the illustrated example of FIG. 4, at block 410, the control circuitry 206 determines an integral parameter based on the negative hysteresis error and the integral gain. For example, the control circuitry 206 determines the integral parameter according to Equation 3 below.

$$Int = {Int}_{PREV} + {G}_{I} * E * DT \qquad Equation 3$$

In Equation 3, Int_{PREV} is the previous value of the integral parameter, G_{I} is the integral gain, E is the hysteresis error, and DT is the upper threshold for the sampling rate of the control circuitry 206 (e.g., one second). In the example of FIG. 4, at block 412, the control circuitry 206 determines a proportional parameter based on the negative hysteresis error and the proportional gain. For example, the control circuitry 206 determines the proportional parameter according to Equation 4 below.

$$Prop = {G}_{P} * E \qquad Equation 4$$

In Equation 4, G_{P} is the proportional gain and E is the hysteresis error. In the example of FIG. 4, at block 414, the control circuitry 206 determines a derivative parameter based on the negative hysteresis error and a derivative gain. For example, the control circuitry 206 determines the derivative parameter according to Equation 5 below.

$$Der = {G}_{D} * \frac{DE}{DT} \qquad Equation 5$$

In Equation 5, G_{D} is the derivative gain, DE is the difference between a current value of the hysteresis error and a previous value of the hysteresis error, and DT is the upper threshold for the sampling rate of the control circuitry 206 (e.g., one second). In the example of FIG. 4, the first value corresponding to the first control response, the second value corresponding to the second control response, the proportional gain, and the derivative gain are programmable values.

In the illustrated example of FIG. 4, at block 416, the control circuitry 206 determines the bandwidth control setting based on a threshold bandwidth, the proportional parameter, the integral parameter, and the derivative parameter. For example, the control circuitry 206 determines the bandwidth control setting according to Equation 6 below.

$${BW}_{CNTRL SETTING} = {BW}_{TH} - Prop - Int - Der \qquad Equation 6$$

In the illustrated example of FIG. 4, at block 418, the control circuitry 206 adjusts the bandwidth control setting based on at least one adjustment threshold for a bandwidth of the memory 106. For example, the at least one adjustment threshold corresponds to an upper threshold and a lower threshold for the bandwidth permitted for the memory 106. In the example of FIG. 4, the at least one adjustment threshold is a programmable value.

As illustrated in FIG. 4, the control circuitry 206 signals the memory control circuitry 120 to throttle the bandwidth of the memory 106 and adjust (e.g., reduce) the input power to the power management circuit 134 over the programmable interval. How quickly the bandwidth of the memory 106 is throttled depends on the parameters of the control algorithm implemented by the control circuitry 206. After block 418, the machine-readable instructions and/or the operations 310 return to the machine-readable instructions and/or the operations 300 at block 312.

As described above, some DIMM configurations exceed the power limit (e.g., 36 W according to JEDEC) for a DIMM and for which the compute platform 100 is designed. As exceeding DIMM configurations are popular among end-users and practical for modern applications, managing the peak power drawn per DIMM allows the compute platform 100 to support a variety of DIMM configurations, including those that would otherwise exceed the power limit for which the compute platform 100 is designed. To manage excessive power based on some usage of the memory 106, the PMU circuitry 104 throttles bandwidth, and thus power drawn, on a per memory instance basis as described above.

As described herein, one or more values are described as programmable. In some examples, one or more of the values are programmed by a manufacturer of the PMU circuitry 104. Additionally or alternatively, one or more of the values are programmed by an end-user of the PMU circuitry 104. In general, the values can be programmed based on testing candidate power thresholds and adjusting candidate intervals to avoid causing the PMU circuitry 104 to adjusting the bandwidth control setting for the memory 106 in response to too many spikes in input power, while considering factors like thermal efficiency, integrity of the compute platform 100, and/or integrity of the memory 106.

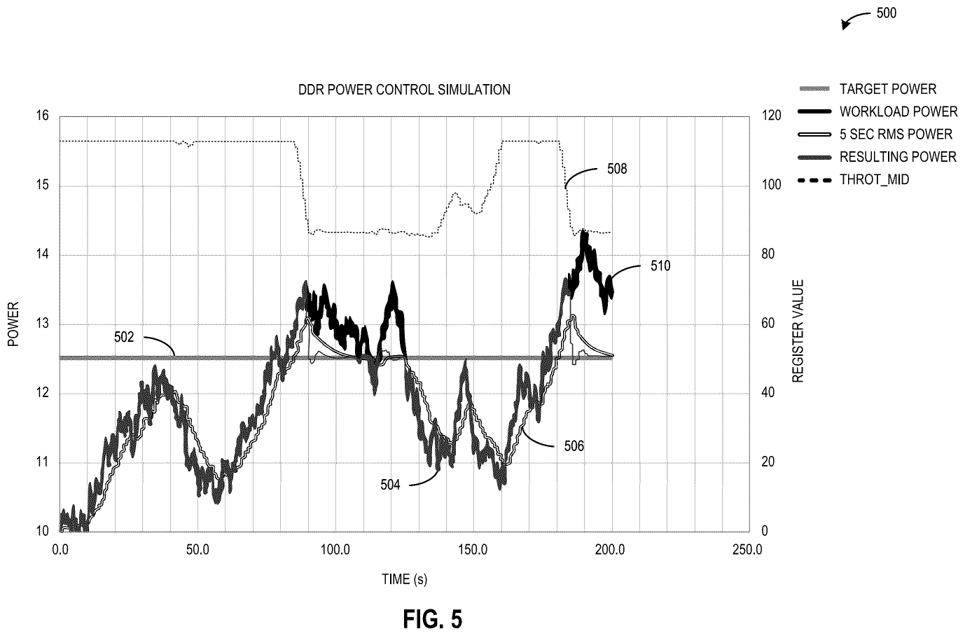

FIG. 5 is a graphical illustration 500 depicting power throttling based on an example threshold input power 502 of 12.5 W. The graphical illustration 500 of FIG. 5 includes a first example plot 504 depicts the input power to the power management circuit 134 as controlled based on the bandwidth to the memory 106 throttled by the PMU circuitry 104. In the example of FIG. 5, the graphical illustration 500 includes a second example plot 506 that depicts the RMS input power to the power management circuit 134. The graphical illustration 500 also includes a third example plot 508 depicting bandwidth control settings generated by the PMU circuitry 104.

In the illustrated example of FIG. 5, the graphical illustration 500 also includes a fourth example plot 510 depicting what the input power to the power management circuit 134 would be without throttling by the PMU circuitry 104. In the example of FIG. 5, the first plot 504, the second plot 506, and the fourth plot 510 are illustrated on a plot of power in watts versus time in seconds and the third plot 508 is illustrated on a plot of register value versus time in seconds. As illustrated in FIG. 5, the PMU circuitry 104 reduces the input power to the power management circuit 134 to be below the threshold input power 502 after an initial delay.

FIG. 6 is a block diagram of an example programmable circuitry platform 600 structured to execute and/or instantiate the example machine-readable instructions and/or the example operations of FIGS. 3 and 4 to implement the PMU circuitry 104 of FIG. 2. The programmable circuitry platform 600 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 600 of the illustrated example includes programmable circuitry 612. The programmable circuitry 612 of the illustrated example is hardware. For example, the programmable circuitry 612 can be implemented by one or more integrated circuits, logic circuits, FPGAs, microprocessors, CPUs, GPUs, VPUs, DSPs, and/or microcontrollers from any desired family or manufacturer. The programmable circuitry 612 may be implemented by one or more semiconductor based (e.g., silicon based) devices. In this example, the programmable circuitry 612 implements the example interface circuitry 202, the example sampling circuitry 204, and the example control circuitry 206.

The programmable circuitry 612 of the illustrated example includes a local memory 613 (e.g., a cache, registers, etc.). The programmable circuitry 612 of the illustrated example is in communication with main memory 614, 616, which includes a volatile memory 614 and a non-volatile memory 616, by a bus 618. The volatile memory 614 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 616 may be implemented by flash memory and/or any other desired type of memory device. Access to the main memory 614, 616 of the illustrated example is controlled by a memory controller 617. In some examples, the memory controller 617 may be implemented by one or more integrated circuits, logic circuits, microcontrollers from any desired family or manufacturer, or any other type of circuitry to manage the flow of data going to and from the main memory 614, 616.

The programmable circuitry platform 600 of the illustrated example also includes interface circuitry 620. The interface circuitry 620 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 622 are connected to the interface circuitry 620. The input device(s) 622 permit(s) a user (e.g., a human user, a machine user, etc.) to enter data and/or commands into the programmable circuitry 612. The input device(s) 622 can be implemented by, for example, an audio sensor, a microphone, a camera (still or video), a keyboard, a button, a mouse, a touchscreen, a trackpad, a trackball, an isopoint device, and/or a voice recognition system.

One or more output devices 624 are also connected to the interface circuitry 620 of the illustrated example. The output device(s) 624 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 620 of the illustrated example, thus, typically includes a graphics driver card, a graphics driver chip, and/or graphics processor circuitry such as a GPU.

The interface circuitry 620 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 626. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 600 of the illustrated example also includes one or more mass storage discs or devices 628 to store firmware, software, and/or data. Examples of such mass storage discs or devices 628 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine-readable instructions 632, which may be implemented by the machine-readable instructions of FIGS. 3 and 4, may be stored in the mass storage device 628, in the volatile memory 614, in the non-volatile memory 616, and/or on at least one non-transitory computer-readable storage medium such as a CD or DVD which may be removable.

FIG. 7 is a block diagram of an example implementation of the programmable circuitry 612 of FIG. 6. In this example, the programmable circuitry 612 of FIG. 6 is implemented by a microprocessor 700. For example, the microprocessor 700 may be a general-purpose microprocessor (e.g., general-purpose microprocessor circuitry). The microprocessor 700 executes some or all of the machine-readable instructions of the flowcharts of FIGS. 3 and 4 to effectively instantiate the circuitry of FIG. 2 as logic circuits to perform operations corresponding to those machine-readable instructions. In some such examples, the circuitry of FIG. 2 is instantiated by the hardware circuits of the microprocessor 700 in combination with the machine-readable instructions. For example, the microprocessor 700 may be implemented by multi-core hardware circuitry such as a CPU, a DSP, a GPU, an XPU, etc. Although it may include any number of example cores 702 (e.g., 1 core), the microprocessor 700 of this example is a multi-core semiconductor device including N cores. The cores 702 of the microprocessor 700 may operate independently or may cooperate to execute machine-readable instructions. For example, machine code corresponding to a firmware program, an embedded software program, or a software program may be executed by one of the cores 702 or may be executed by multiple ones of the cores 702 at the same or different times. In some examples, the machine code corresponding to the firmware program, the embedded software program, or the software program is split into threads and executed in parallel by two or more of the cores 702. The software program may correspond to a portion or all of the machine-readable instructions and/or operations represented by the flowcharts of FIGS. 3 and 4.

The cores 702 may communicate by a first example bus 704. In some examples, the first bus 704 may be implemented by a communication bus to effectuate communication associated with one(s) of the cores 702. For example, the first bus 704 may be implemented by at least one of an Inter-Integrated Circuit (I2C) bus, a Serial Peripheral Interface (SPI) bus, a PCI bus, or a PCIe bus. Additionally or alternatively, the first bus 704 may be implemented by any other type of computing or electrical bus. The cores 702 may obtain data, instructions, and/or signals from one or more external devices by example interface circuitry 706. The cores 702 may output data, instructions, and/or signals to the one or more external devices by the interface circuitry 706. Although the cores 702 of this example include example local memory 720 (e.g., Level 1 (L1) cache that may be split into an L1 data cache and an L1 instruction cache), the microprocessor 700 also includes example shared memory 710 that may be shared by the cores (e.g., Level 2 (L2 cache)) for high-speed access to data and/or instructions. Data and/or instructions may be transferred (e.g., shared) by writing to and/or reading from the shared memory 710. The local memory 720 of each of the cores 702 and the shared memory 710 may be part of a hierarchy of storage devices including multiple levels of cache memory and the main memory (e.g., the main memory 614, 616 of FIG. 6). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 702 may be referred to as a CPU, DSP, GPU, etc., or any other type of hardware circuitry. Each core 702 includes control unit circuitry 714, arithmetic and logic (AL) circuitry 716 (sometimes referred to as an ALU), a plurality of registers 718, the local memory 720, and a second example bus 722. Other structures may be present. For example, each core 702 may include vector unit circuitry, single instruction multiple data (SIMD) unit circuitry, load/store unit (LSU) circuitry, branch/jump unit circuitry, floating-point unit (FPU) circuitry, etc. The control unit circuitry 714 includes semiconductor-based circuits structured to control (e.g., coordinate) data movement within the corresponding core 702. The AL circuitry 716 includes semiconductor-based circuits structured to perform one or more mathematic and/or logic operations on the data within the corresponding core 702. The AL circuitry 716 of some examples performs integer-based operations. In other examples, the AL circuitry 716 also performs floating-point operations. In yet other examples, the AL circuitry 716 may include first AL circuitry that performs integer-based operations and second AL circuitry that performs floating-point operations. In some examples, the AL circuitry 716 may be referred to as an Arithmetic Logic Unit (ALU).

The registers 718 are semiconductor-based structures to store data and/or instructions such as results of one or more of the operations performed by the AL circuitry 716 of the corresponding core 702. For example, the registers 718 may include vector register(s), SIMD register(s), general-purpose register(s), flag register(s), segment register(s), machine-specific register(s), instruction pointer register(s), control register(s), debug register(s), memory management register(s), machine check register(s), etc. The registers 718 may be arranged in a bank as shown in FIG. 7. Alternatively, the registers 718 may be organized in any other arrangement, format, or structure, such as by being distributed throughout the core 702 to shorten access time. The second bus 722 may be implemented by at least one of an I2C bus, a SPI bus, a PCI bus, or a PCIe bus.

Each core 702 and/or, more generally, the microprocessor 700 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 700 is a semiconductor device fabricated to include many transistors interconnected to implement the structures described above in one or more integrated circuits (ICs) contained in one or more packages.

The microprocessor 700 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on board the microprocessor 700, in the same chip package as the microprocessor 700 and/or in one or more separate packages from the microprocessor 700.

FIG. 8 is a block diagram of another example implementation of the programmable circuitry 612 of FIG. 6. In this example, the programmable circuitry 612 is implemented by FPGA circuitry 800. For example, the FPGA circuitry 800 may be implemented by an FPGA. The FPGA circuitry 800 can be used, for example, to perform operations that could otherwise be performed by the example microprocessor 700 of FIG. 7 executing corresponding machine-readable instructions. However, once configured, the FPGA circuitry 800 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 700 of FIG. 7 described above (which is a general purpose device that may be programmed to execute some or all of the machine-readable instructions represented by the flowchart(s) of FIGS. 3 and 4 but whose interconnections and logic circuitry are fixed once fabricated), the FPGA circuitry 800 of the example of FIG. 8 includes interconnections and logic circuitry that may be configured, structured, programmed, and/or interconnected in different ways after fabrication to instantiate, for example, some or all of the operations/functions corresponding to the machine-readable instructions represented by the flowchart(s) of FIGS. 3 and 4. In particular, the FPGA circuitry 800 may be thought of as an array of logic gates, interconnections, and switches. The switches can be programmed to change how the logic gates are interconnected by the interconnections, effectively forming one or more dedicated logic circuits (unless and until the FPGA circuitry 800 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 3 and 4. As such, the FPGA circuitry 800 may be configured and/or structured to effectively instantiate some or all of the operations/functions corresponding to the machine-readable instructions of the flowchart(s) of FIGS. 3 and 4 as dedicated logic circuits to perform the operations/functions corresponding to those software instructions in a dedicated manner analogous to an ASIC. Therefore, the FPGA circuitry 800 may perform the operations/functions corresponding to the some or all of the machine-readable instructions of FIGS. 3 and 4 faster than the general-purpose microprocessor can execute the same.

In the example of FIG. 8, the FPGA circuitry 800 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 800 of FIG. 8 may access and/or load the binary file to cause the FPGA circuitry 800 of FIG. 8 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 800 of FIG. 8 to cause configuration and/or structuring of the FPGA circuitry 800 of FIG. 8, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 800 of FIG. 8 may access and/or load the binary file to cause the FPGA circuitry 800 of FIG. 8 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 800 of FIG. 8 to cause configuration and/or structuring of the FPGA circuitry 800 of FIG. 8, or portion(s) thereof.

The FPGA circuitry 800 of FIG. 8, includes example input/output (I/O) circuitry 802 to obtain and/or output data to/from example configuration circuitry 804 and/or external hardware 806. For example, the configuration circuitry 804 may be implemented by interface circuitry that may obtain a binary file, which may be implemented by a bit stream, data, and/or machine-readable instructions, to configure the FPGA circuitry 800, or portion(s) thereof. In some such examples, the configuration circuitry 804 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 806 may be implemented by external hardware circuitry. For example, the external hardware 806 may be implemented by the microprocessor 700 of FIG. 7.

The FPGA circuitry 800 also includes an array of example logic gate circuitry 808, a plurality of example configurable interconnections 810, and example storage circuitry 812. The logic gate circuitry 808 and the configurable interconnections 810 are configurable to instantiate one or more operations/functions that may correspond to at least some of the machine-readable instructions of FIGS. 3 and 4 and/or other desired operations. The logic gate circuitry 808 shown in FIG. 8 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 808 to enable configuration of the electrical structures and/or the logic gates to form circuits to perform desired operations/functions. The logic gate circuitry 808 may include other electrical structures such as look-up tables (LUTs), registers (e.g., flip-flops or latches), multiplexers, etc.

The configurable interconnections 810 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 808 to program desired logic circuits.

The storage circuitry 812 of the illustrated example is structured to store result(s) of the one or more of the operations performed by corresponding logic gates. The storage circuitry 812 may be implemented by registers or the like. In the illustrated example, the storage circuitry 812 is distributed amongst the logic gate circuitry 808 to facilitate access and increase execution speed.

The example FPGA circuitry 800 of FIG. 8 also includes example dedicated operations circuitry 814. In this example, the dedicated operations circuitry 814 includes special purpose circuitry 816 that may be invoked to implement commonly used functions to avoid the need to program those functions in the field. Examples of such special purpose circuitry 816 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 800 may also include example general purpose programmable circuitry 818 such as an example CPU 820 and/or an example DSP 822. Other general purpose programmable circuitry 818 may additionally or alternatively be present such as a GPU, an XPU, etc., that can be programmed to perform other operations.

Although FIGS. 7 and 8 illustrate two example implementations of the programmable circuitry 612 of FIG. 6, many other approaches are contemplated. For example, FPGA circuitry may include an on-board CPU, such as one or more of the example CPU 820 of FIG. 7. Therefore, the programmable circuitry 612 of FIG. 6 may additionally be implemented by combining at least the example microprocessor 700 of FIG. 7 and the example FPGA circuitry 800 of FIG. 8. In some such hybrid examples, one or more cores 702 of FIG. 7 may execute a first portion of the machine-readable instructions represented by the flowchart(s) of FIGS. 3 and 4 to perform first operation(s)/function(s), the FPGA circuitry 800 of FIG. 8 may be configured and/or structured to perform second operation(s)/function(s) corresponding to a second portion of the machine-readable instructions represented by the flowcharts of FIGS. 3 and 4, and/or an ASIC may be configured and/or structured to perform third operation(s)/function(s) corresponding to a third portion of the machine-readable instructions represented by the flowcharts of FIGS. 3 and 4.

It should be understood that some or all of the circuitry of FIG. 2 may, thus, be instantiated at the same or different times. For example, same and/or different portion(s) of the microprocessor 700 of FIG. 7 may be programmed to execute portion(s) of machine-readable instructions at the same and/or different times. In some examples, same and/or different portion(s) of the FPGA circuitry 800 of FIG. 8 may be configured and/or structured to perform operations/functions corresponding to portion(s) of machine-readable instructions at the same and/or different times.

In some examples, some or all of the circuitry of FIG. 2 may be instantiated, for example, in one or more threads executing concurrently and/or in series. For example, the microprocessor 700 of FIG. 7 may execute machine-readable instructions in one or more threads executing concurrently and/or in series. In some examples, the FPGA circuitry 800 of FIG. 8 may be configured and/or structured to carry out operations/functions concurrently and/or in series. Moreover, in some examples, some or all of the circuitry of FIG. 2 may be implemented within one or more virtual machines and/or containers executing on the microprocessor 700 of FIG. 7.

In some examples, the programmable circuitry 612 of FIG. 6 may be in one or more packages. For example, the microprocessor 700 of FIG. 7 and/or the FPGA circuitry 800 of FIG. 8 may be in one or more packages. In some examples, an XPU may be implemented by the programmable circuitry 612 of FIG. 6, which may be in one or more packages. For example, the XPU may include a CPU (e.g., the microprocessor 700 of FIG. 7, the CPU 820 of FIG. 8, etc.) in one package, a DSP (e.g., the DSP 822 of FIG. 8) in another package, a GPU in yet another package, and an FPGA (e.g., the FPGA circuitry 800 of FIG. 8) in still yet another package.

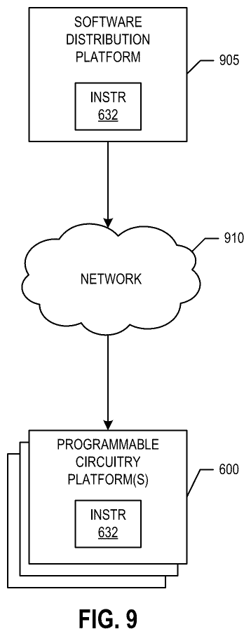

A block diagram illustrating an example software distribution platform 905 to distribute software such as the example machine-readable instructions 632 of FIG. 6 to other hardware devices (e.g., hardware devices owned and/or operated by third parties from the owner and/or operator of the software distribution platform) is illustrated in FIG. 9. The example software distribution platform 905 may be implemented by any computer server, data facility, cloud service, etc., capable of storing and transmitting software to other computing devices. The third parties may be customers of the entity owning and/or operating the software distribution platform 905. For example, the entity that owns and/or operates the software distribution platform 905 may be a developer, a seller, and/or a licensor of software such as the example machine-readable instructions 632 of FIG. 6. The third parties may be consumers, users, retailers, OEMs, etc., who purchase and/or license the software for use and/or re-sale and/or sub-licensing. In the illustrated example, the software distribution platform 905 includes one or more servers and one or more storage devices. The storage devices store the machine-readable instructions 632, which may correspond to the example machine-readable instructions of FIGS. 3 and 4, as described above. The one or more servers of the example software distribution platform 905 are in communication with an example network 910, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third-party payment entity. The servers enable purchasers and/or licensors to download the machine-readable instructions 632 from the software distribution platform 905. For example, the software, which may correspond to the example machine-readable instructions of FIGS. 3 and 4, may be downloaded to the example programmable circuitry platform 600, which is to execute the machine-readable instructions 632 to implement the PMU circuitry 104. In some examples, one or more servers of the software distribution platform 905 periodically offer, transmit, and/or force updates to the software (e.g., the example machine-readable instructions 632 of FIG. 6) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions or values that may not be exact due to manufacturing tolerances and/or other real-world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that throttle power to DDR memory in server platforms. For example, disclosed systems, apparatus, articles of manufacture, and methods allow a compute platform to include higher density and/or higher capacity registered DIMM (RDIMM) and/or MRDIMM. As such, examples disclosed herein allow a compute platform to run any workload and also protect both the compute platform and DIMMs when workload power usage exceeds what the platform and/or DIMM are designed to accommodate.

Disclosed systems, apparatus, articles of manufacture, and methods improve the efficiency of using a computing device by supporting more performant DIMM configurations that would otherwise draw excessive power and cause damage to the computing device and/or DIMMs of the computing device. For example, disclosed systems, apparatus, articles of manufacture, and methods allow for a greater number of DIMM configurations for end-users of a compute platform and allow for the compute platform and/or DIMM to support workloads that occasionally may exceed the DIMM power limit for a limited time (e.g., as the majority of workloads are intermittent). Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to throttle memory bandwidth for power management are disclosed herein. Further examples and combinations thereof include the following:

Example 1 includes an apparatus comprising machine-readable instructions, and at least one programmable circuit to be programmed by the machine-readable instructions to determine an output power from a power management circuit of a memory, determine an input power to the power management circuit based on the output power, and based on the input power and a threshold power, adjust a bandwidth control setting of the memory.

Example 2 includes the apparatus of example 1, wherein one or more of the at least one programmable circuit is to determine the input power based on the output power and an efficiency of the power management circuit.

Example 3 includes the apparatus of any of examples 1 or 2, wherein the output power is a first output power, the input power is a first input power, the bandwidth control setting is a first bandwidth control setting, the power management circuit is a first power management circuit, the memory is a first memory, and one or more of the at least one programmable circuit is to determine a second output power from a second power management circuit of a second memory on a same channel as the first memory, determine a second input power to the second power management circuit based on the second output power, and based on the second input power and the threshold power, adjust a second bandwidth control setting of the second memory.

Example 4 includes the apparatus of any of examples 1, 2, or 3, wherein one or more of the at least one programmable circuit is to determine the input power to the power management circuit for a first interval, and based on the input power and the threshold power, adjust the bandwidth control setting of the memory for a second interval.

Example 5 includes the apparatus of example 4, wherein one or more of the at least one programmable circuit is to adjust the bandwidth control setting of the memory to cause the input power for the second interval to satisfy the threshold power for the memory.

Example 6 includes the apparatus of any of examples 1, 2, 3, 4, or 5, wherein one or more of the at least one programmable circuit is to determine the output power based on at least one register indicating at least one of an output current from the power management circuit or the output power from the power management circuit.

Example 7 includes the apparatus of any of examples 1, 2, 3, 4, 5, or 6, wherein one or more of the at least one programmable circuit is to add a first value read from a first register of the power management circuit and a second value read from a second register of the power management circuit to determine the output power.

Example 8 includes the apparatus of any of examples 1, 2, 3, 4, 5, 6, or 7, wherein one or more of the at least one programmable circuit is to determine whether the input power satisfies the threshold power.

Example 9 includes the apparatus of example 8, wherein one or more of the at least one programmable circuit is to, based on the input power not satisfying the threshold power determine the bandwidth control setting for the memory based on a controller, and provide the bandwidth control setting to an actuator to cause the actuator to adjust a bandwidth of the memory.

Example 10 includes the apparatus of example 9, wherein the controller includes at least one of an artificial intelligence controller or a proportional, integral, derivative controller.

Example 11 includes the apparatus of example 10, wherein the artificial intelligence controller includes a neural network controller.

Example 12 includes the apparatus of any of examples 1, 2, 3, 4, 5, 6, 7, 8, 9, 10, or 11, wherein the memory includes at least one dual in-line memory module.

Example 13 includes the apparatus of any of examples 1, 2, 3, 4, 5, 6, 7, 8, 9, 10, 11, or 12, wherein the threshold power is a programmable value.

Example 14 includes a non-transitory computer-readable medium comprising instructions to cause at least one programmable circuit to determine an output power from a power management circuit of a memory, determine an input power to the power management circuit based on the output power, and based on the input power and a threshold power, adjust a bandwidth control setting of the memory.

Example 15 includes the non-transitory computer-readable medium of example 14, wherein the instructions cause one or more of the at least one programmable circuit to determine the input power based on the output power and an efficiency of the power management circuit.

Example 16 includes the non-transitory computer-readable medium of any of examples 14 or 15, wherein the output power is a first output power, the input power is a first input power, the bandwidth control setting is a first bandwidth control setting, the power management circuit is a first power management circuit, the memory is a first memory, and the instructions cause one or more of the at least one programmable circuit to determine a second output power from a second power management circuit of a second memory on a same channel as the first memory, determine a second input power to the second power management circuit based on the second output power, and based on the second input power and the threshold power, adjust a second bandwidth control setting of the second memory.

Example 17 includes the non-transitory computer-readable medium of any of examples 14, 15, or 16, wherein the instructions cause one or more of the at least one programmable circuit to determine the input power to the power management circuit for a first interval, and based on the input power and the threshold power, adjust the bandwidth control setting of the memory for a second interval.

Example 18 includes the non-transitory computer-readable medium of example 17, wherein the instructions cause one or more of the at least one programmable circuit to adjust the bandwidth control setting of the memory to cause the input power for the second interval to satisfy the threshold power for the memory.

Example 19 includes the non-transitory computer-readable medium of any of examples 14, 15, 16, 17, or 18, wherein the instructions cause one or more of the at least one programmable circuit to determine the output power based on at least one register indicating at least one of an output current from the power management circuit or the output power from the power management circuit.

Example 20 includes the non-transitory computer-readable medium of any of examples 14, 15, 16, 17, 18, or 19, wherein the instructions cause one or more of the at least one programmable circuit to add a first value read from a first register of the power management circuit and a second value read from a second register of the power management circuit to determine the output power.

Example 21 includes the non-transitory computer-readable medium of any of examples 14, 15, 16, 17, 18, 19, or 20, wherein the instructions cause one or more of the at least one programmable circuit to determine whether the input power satisfies the threshold power.

Example 22 includes the non-transitory computer-readable medium of example 21, wherein the instructions cause one or more of the at least one programmable circuit to, based on the input power not satisfying the threshold power determine the bandwidth control setting for the memory based on a controller, and provide the bandwidth control setting to an actuator to cause the actuator to adjust a bandwidth of the memory.

Example 23 includes the non-transitory computer-readable medium of example 22, wherein the controller includes at least one of an artificial intelligence controller or a proportional, integral, derivative controller.

Example 24 includes the non-transitory computer-readable medium of example 23, wherein the artificial intelligence controller includes a neural network controller.

Example 25 includes the non-transitory computer-readable medium of any of examples 14, 15, 16, 17, 18, 19, 20, 21, 22, 23, or 24, wherein the memory includes at least one dual in-line memory module.

Example 26 includes the non-transitory computer-readable medium of any of examples 14, 15, 16, 17, 18, 19, 20, 21, 22, 23, 24, or 25, wherein the threshold power is a programmable value.

Example 27 includes a method comprising determining an output power from a power management circuit of a memory, determining an input power to the power management circuit based on the output power, and based on the input power and a threshold power, adjusting a bandwidth control setting of the memory.

Example 28 includes the method of example 27, including determining the input power based on the output power and an efficiency of the power management circuit.

Example 29 includes the method of any of examples 27 or 28, wherein the output power is a first output power, the input power is a first input power, the bandwidth control setting is a first bandwidth control setting, the power management circuit is a first power management circuit, the memory is a first memory, and the method includes determining a second output power from a second power management circuit of a second memory on a same channel as the first memory, determining a second input power to the second power management circuit based on the second output power, and based on the second input power and the threshold power, adjusting a second bandwidth control setting of the second memory.

Example 30 includes the method of any of examples 27, 28, or 29, including determining the input power to the power management circuit for a first interval, and based on the input power and the threshold power, adjusting the bandwidth control setting of the memory for a second interval.

Example 31 includes the method of example 30, including adjusting the bandwidth control setting of the memory to cause the input power for the second interval to satisfy the threshold power for the memory.

Example 32 includes the method of any of examples 27, 28, 29, 30, or 31, including determining the output power based on at least one register indicating at least one of an output current from the power management circuit or the output power from the power management circuit.

Example 33 includes the method of any of examples 27, 28, 29, 30, 31, or 32, including adding a first value read from a first register of the power management circuit and a second value read from a second register of the power management circuit to determine the output power.

Example 34 includes the method of any of examples 27, 28, 29, 30, 31, 32, or 33, including determining whether the input power satisfies the threshold power.

Example 35 includes the method of example 34, including, based on the input power not satisfying the threshold power determining the bandwidth control setting for the memory based on a controller, and providing the bandwidth control setting to an actuator to cause the actuator to adjust a bandwidth of the memory.

Example 36 includes the method of example 35, wherein the controller includes at least one of an artificial intelligence controller or a proportional, integral, derivative controller.

Example 37 includes the method of example 36, wherein the artificial intelligence controller includes a neural network controller.

Example 38 includes the method of any of examples 27, 28, 29, 30, 31, 32, 33, 34, 35, 36, or 37, wherein the memory includes at least one dual in-line memory module.

Example 39 includes the method of any of examples 27, 28, 29, 30, 31, 32, 33, 34, 35, 36, 37, or 38, wherein the threshold power is a programmable value.

Example 40 includes an apparatus comprising means for determining an input power to a power management circuit of a memory based on an output power from the power management circuit, and means for adjusting a bandwidth control setting of the memory based on the input power and a threshold power.

Example 41 includes the apparatus of example 40, wherein the means for determining is to determine the input power based on the output power and an efficiency of the power management circuit.

Example 42 includes the apparatus of any of examples 40 or 41, wherein the output power is a first output power, the input power is a first input power, the bandwidth control setting is a first bandwidth control setting, the power management circuit is a first power management circuit, the memory is a first memory, and the means for determining is to determine a second input power to a second power management circuit of a second memory on a same channel as the first memory based on a second output power from the second power management circuit, and the means for adjusting is to, based on the second input power and the threshold power, adjust a second bandwidth control setting of the second memory.

Example 43 includes the apparatus of any of examples 40, 41, or 42, wherein the means for determining is to determine the input power to the power management circuit for a first interval, and the means for adjusting is to, based on the input power and the threshold power, adjust the bandwidth control setting of the memory for a second interval.

Example 44 includes the apparatus of example 43, wherein the means for adjusting is to adjust the bandwidth control setting of the memory to cause the input power for the second interval to satisfy the threshold power for the memory.

Example 45 includes the apparatus of any of examples 40, 41, 42, 43, or 44, wherein the means for determining is to determine the output power based on at least one register indicating at least one of an output current from the power management circuit or the output power from the power management circuit.

Example 46 includes the apparatus of any of examples 40, 41, 42, 43, 44, or 45, wherein the means for determining is to add a first value read from a first register of the power management circuit and a second value read from a second register of the power management circuit to determine the output power.

Example 47 includes the apparatus of any of examples 40, 41, 42, 43, 44, 45, or 46, wherein the means for adjusting is to determine whether the input power satisfies the threshold power.

Example 48 includes the apparatus of example 47, wherein the means for adjusting is to, based on the input power not satisfying the threshold power determine the bandwidth control setting for the memory based on a controller, and provide the bandwidth control setting to an actuator to cause the actuator to adjust a bandwidth of the memory.

Example 49 includes the apparatus of example 48, wherein the controller includes at least one of an artificial intelligence controller or a proportional, integral, derivative controller.

Example 50 includes the apparatus of example 49, wherein the artificial intelligence controller includes a neural network controller.

Example 51 includes the apparatus of any of examples 40, 41, 42, 43, 44, 45, 46, 47, 48, 49, or 50, wherein the memory includes at least one dual in-line memory module.

Example 52 includes the apparatus of any of examples 40, 41, 42, 43, 44, 45, 46, 47, 48, 49, 50, or 51, wherein the threshold power is a programmable value.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
machine-readable instructions; and
at least one programmable circuit to be programmed by the machine-readable instructions to:
determine an output power from a power management circuit of a memory;
determine an input power to the power management circuit based on the output power; and
based on the input power and a threshold power, adjust a bandwidth control setting of the memory.

2. The apparatus of claim 1, wherein one or more of the at least one programmable circuit is to determine the input power based on the output power and an efficiency of the power management circuit.

3. The apparatus of claim 1, wherein the output power is a first output power, the input power is a first input power, the bandwidth control setting is a first bandwidth control setting, the power management circuit is a first power management circuit, the memory is a first memory, and one or more of the at least one programmable circuit is to:
determine a second output power from a second power management circuit of a second memory on a same channel as the first memory;
determine a second input power to the second power management circuit based on the second output power; and
based on the second input power and the threshold power, adjust a second bandwidth control setting of the second memory.

4. The apparatus of claim 1, wherein one or more of the at least one programmable circuit is to:
determine the input power to the power management circuit for a first interval; and
based on the input power and the threshold power, adjust the bandwidth control setting of the memory for a second interval.

5. (canceled)

6. The apparatus of claim 1, wherein one or more of the at least one programmable circuit is to determine the output power based on at least one register indicating at least one of an output current from the power management circuit or the output power from the power management circuit.

7. The apparatus of claim 1, wherein one or more of the at least one programmable circuit is to add a first value read from a first register of the power management circuit and a second value read from a second register of the power management circuit to determine the output power.

8.-11. (canceled)

12. The apparatus of claim 1, wherein the memory includes at least one dual in-line memory module.

13. (canceled)

14. A non-transitory computer-readable medium comprising instructions to cause at least one programmable circuit to:
determine an output power from a power management circuit of a memory;
determine an input power to the power management circuit based on the output power; and
based on the input power and a threshold power, adjust a bandwidth control setting of the memory.

15.-16. (canceled)

17. The non-transitory computer-readable medium of claim 14, wherein the instructions cause one or more of the at least one programmable circuit to:
determine the input power to the power management circuit for a first interval; and
based on the input power and the threshold power, adjust the bandwidth control setting of the memory for a second interval.

18. The non-transitory computer-readable medium of claim 17, wherein the instructions cause one or more of the at least one programmable circuit to adjust the bandwidth control setting of the memory to cause the input power for the second interval to satisfy the threshold power for the memory.

19.-20. (canceled)

21. The non-transitory computer-readable medium of claim 14, wherein the instructions cause one or more of the at least one programmable circuit to determine whether the input power satisfies the threshold power.

22. The non-transitory computer-readable medium of claim 21, wherein the instructions cause one or more of the at least one programmable circuit to, based on the input power not satisfying the threshold power:
determine the bandwidth control setting for the memory based on a controller; and
provide the bandwidth control setting to an actuator to cause the actuator to adjust a bandwidth of the memory.

23. The non-transitory computer-readable medium of claim 22, wherein the controller includes at least one of an artificial intelligence controller or a proportional, integral, derivative controller.

24. The non-transitory computer-readable medium of claim 23, wherein the artificial intelligence controller includes a neural network controller.

25.-39. (canceled)

40. An apparatus comprising:
means for determining an input power to a power management circuit of a memory based on an output power from the power management circuit; and
means for adjusting a bandwidth control setting of the memory based on the input power and a threshold power.

41. The apparatus of claim 40, wherein the means for determining is to determine the input power based on the output power and an efficiency of the power management circuit.

42. The apparatus of claim 40, wherein the output power is a first output power, the input power is a first input power, the bandwidth control setting is a first bandwidth control setting, the power management circuit is a first power management circuit, the memory is a first memory, and:
the means for determining is to determine a second input power to a second power management circuit of a second memory on a same channel as the first memory based on a second output power from the second power management circuit; and
the means for adjusting is to, based on the second input power and the threshold power, adjust a second bandwidth control setting of the second memory.

43.-45. (canceled)

46. The apparatus of claim 40, wherein the means for determining is to add a first value read from a first register of the power management circuit and a second value read from a second register of the power management circuit to determine the output power.

47.-50. (canceled)

51. The apparatus of claim 40, wherein the memory includes at least one dual in-line memory module.

52. The apparatus of claim 40, wherein the threshold power is a programmable value.
